(19) United States
(12) Patent Application Publication
(10) Pub. No.: US 2024/0266200 A1
(43) Pub. Date: Aug. 8, 2024

(54) Electrostatic Chuck

(71) Applicant: Applied Materials, Inc., Santa Clara, CA (US)

(72) Inventors: Sarath BABU, Singapore (RS); Mukund SUNDARARAJAN, Bangalore (IN); Cheng-Hsiung TSAI, Cupertino, CA (US); Ananthkrishna JUPUDI, Singapore (SG); Ross MARSHALL, Campbell, CA (US)

(21) Appl. No.: 18/107,157

(22) Filed: Feb. 8, 2023

(51) Int. Cl. H01L 21/683; H01L 21/67

(52) U.S. Cl. CPC H01L 21/6833; H01L 21/67103

(57) ABSTRACT

An electrostatic chuck assembly including a body including a body recess and a heat transfer plate disposed in the body recess, wherein the heat transfer plate includes an upper surface, a lower surface, a first opening, and a second opening. The electrostatic chuck assembly further includes an RF transmission tube configured to transfer RF power to the lower surface of the heat transfer plate. The electrostatic chuck assembly further includes a puck bonded to the upper surface of the heat transfer plate. The electrostatic chuck assembly further includes a first chucking electrode disposed in the first opening and a second chucking electrode is disposed in the second opening, wherein the first and second chucking electrodes are configured to transfer a chucking voltage to the puck.

### BACKGROUND

### Field

Embodiments of the present disclosure relate to the microelectronics manufacturing industry and more particularly to electrostatic chucks for supporting a substrate during semiconductor processing.

### Description of the Related Art

Electrostatic chucks are widely used to hold substrates, such as semiconductor wafers, during processing in processing chambers. Conventional electrostatic chucks typically include one or more electrodes embedded within a unitary chuck body which comprises a dielectric or semi-conductive ceramic material across which an electrostatic clamping field can be generated. Semi-conductive ceramic materials, such as aluminum nitride, boron nitride, or aluminum oxide doped with a metal oxide, for example, may be used to enable Johnsen-Rahbek or non-Coulombic electrostatic clamping fields to be generated.

However, it is difficult to embed metal components (e.g., electrodes) within the ceramic chuck body because of differences in the thermal expansion coefficients of the ceramic and metal which can result in thermo-mechanical stresses that can cause the ceramic to fracture or chip during thermal cycling. Additionally, differences in the thermal expansion coefficients may increase with temperature resulting in greater thermo-mechanical stresses at higher temperatures. To compensate for these stresses, the ceramic chuck body is made thicker to provide greater strength and prevent fracture. Increasing the thickness of the chuck body increases manufacturing costs.

Conventional electrostatic chucks are used to process substrates with plasma. RF power is applied to the embedded electrodes to ignite a plasma by generating a magnetic field that ignites processes gases to form a plasma. However, conventional chucks have a tendency to generate a magnetic field that is shifted to one side of the chuck such that the plasma is not uniformly distributed above the substrate. This uneven distribution of the plasma, for example, can result in an uneven etch rate across the substrate. As a result, additional processing must be completed to compensate for the effects on an uneven distribution of the plasma.

Accordingly, there is a need in the art for a cost effective electrostatic chuck that can operate at high temperatures and over a wide range of temperatures in a high vacuum environment without failure. Additionally, a need exists for a cost effective electrostatic chuck which can create an electromagnetic field with a reduced or eliminated shift.

### SUMMARY

In one embodiment, an electrostatic chuck assembly includes a body, a heat transfer plate, and RF transmission tube, a puck, a first chucking electrode, and a second chucking electrode. The body includes a body recess. The heat transfer plate is disposed in the body recess. The heat transfer plate includes an upper surface, a lower surface, a coolant channel, a first opening, and a second opening. The RF transmission tube is configured to transfer RF power to the heat transfer plate. The heat transfer plate includes a shaft connected to a head with a head recess formed therein. A head shoulder of the head contacts a continuous area of the lower surface of the heat transfer plate. The puck is engaged with the upper surface of the heat transfer plate. The first chucking electrode is disposed in the first opening and the second chucking electrode is disposed in the second opening. The first and second chucking electrodes are configured to transfer a chucking voltage to the puck.

In one embodiment, an electrostatic chuck assembly including a body including a body recess and a heat transfer plate disposed in the body recess, wherein the heat transfer plate includes an upper surface, a lower surface, a first opening, and a second opening. The electrostatic chuck assembly further includes an RF transmission tube configured to transfer RF power to the lower surface of the heat transfer plate. The electrostatic chuck assembly further includes a puck bonded to the upper surface of the heat transfer plate. The electrostatic chuck assembly further includes a first chucking electrode disposed in the first opening and a second chucking electrode is disposed in the second opening, wherein the first and second chucking electrodes are configured to transfer a chucking voltage to the puck.

In one embodiment, a method of processing a substrate includes chucking a first substrate to a puck bonded to an upper surface of a heat transfer plate by applying a chucking voltage to the puck using a first chucking electrode and a second chucking electrode disposed in the heat transfer plate. The first and second chucking electrode have opposing polarities. The method further includes igniting a plasma above the first substrate chucked to the puck using a first RF power. The first RF power is transferred from an RF transmission tube to the heat transfer plate at a continuous interface between the heat transfer plate and an RF transmission tube. The method further includes processing the first substrate using a second RF power. The second RF power is transferred from the RF transmission tube to the heat transfer plate at the continuous interface.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1 depicts a schematic illustration of a process station, according to one embodiment.

FIG. 2A is a cross-sectional view of an electrostatic chuck assembly according to one embodiment.

FIG. 2B is a cross-sectional view of the electrostatic chuck assembly according to the embodiment shown in FIG. 2A.

FIG. 2C is a top perspective view of a puck bonded to a heat transfer plate of the electrostatic chuck assembly, according to the embodiment shown in FIG. 2A.

FIG. 3 is a partial cross-sectional view of the puck bonded to the heat transfer plate from the region labeled FIG. 3 shown in FIG. 2A.

FIG. 4 is a flowchart of a method of processing a substrate in the process station of FIG. 1 using the electrostatic chuck assembly of FIGS. 2A-C and 3.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments herein are generally directed to a bipolar electrostatic chuck used during the processing of a substrate, such as a semiconductor substrate.

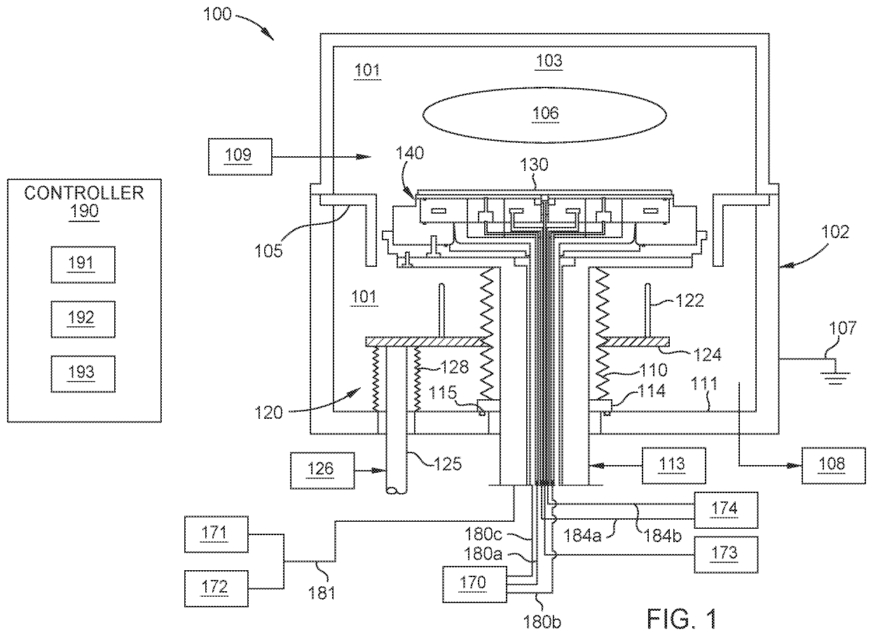

FIG. 1 is a schematic cross-sectional view of a process station 100 according to one embodiment of the disclosure. In one embodiment, the process chamber is a sputter etch processing chamber. However, the process station 100 may be configured to complete other processes, such as physical vapor deposition or chemical vapor deposition.

Process station 100 is a chamber which is suitably adapted to maintain a processing pressure within during substrate processing. The process station 100 includes a chamber body 102 which encloses an interior volume 101. A processing volume 103 is located in the upper portion of the interior volume 101. The processing volume 103 may be maintained at sub-atmospheric pressures during processing. The process station 100 may also include one or more shields 105 circumscribing various chamber components to prevent unwanted reaction between such components and ionized process material. The chamber body 102 may be made of metal, such as aluminum. The chamber body 102 is also connected to a ground 107.

The process station 100 includes an exhaust 108 to remove gases from the interior volume 101. A processing pressure may be maintained and/or adjusted using exhaust 108. The exhaust 108 may include one or more pumps. For example, the exhaust 108 may include a throttle valve (not shown) and vacuum pump (not shown) which are used to evacuate the interior volume 101. The pressure inside the process station 100 may be regulated by adjusting the throttle valve and/or vacuum pump. In some embodiments, the exhaust 108 is used to maintain the pressure within the processing volume 103 at sub-atmospheric conditions. The process station 100 is coupled to a gas supply 109 which introduces gases, such as one or more process gases, into the processing volume 103. One or more gases delivered into the processing volume 103 from the gas supply 109 may be ignited into and maintained as a plasma 106 by an electrostatic chuck assembly 140.

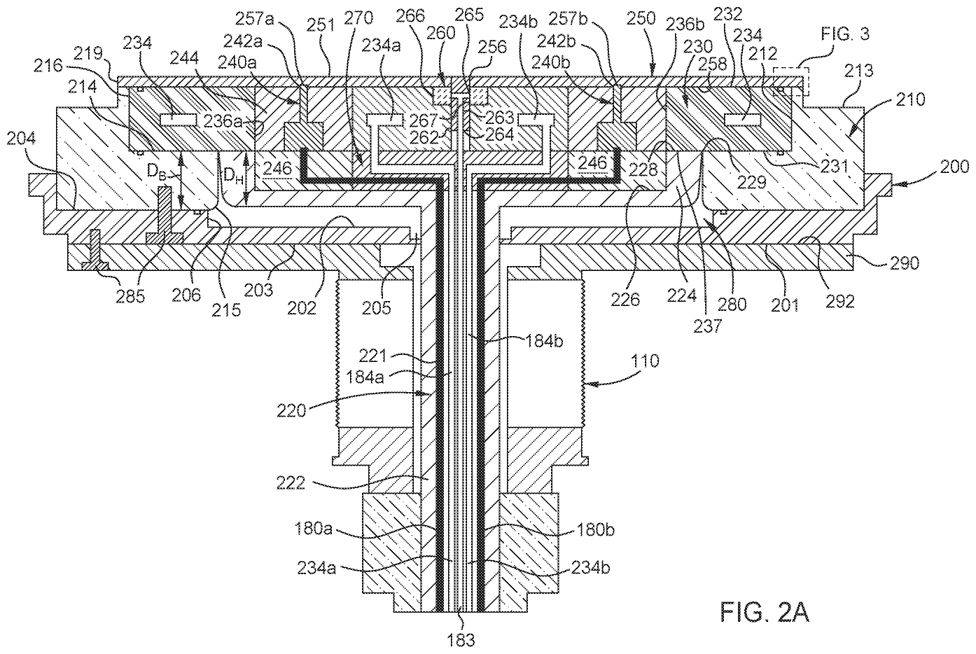

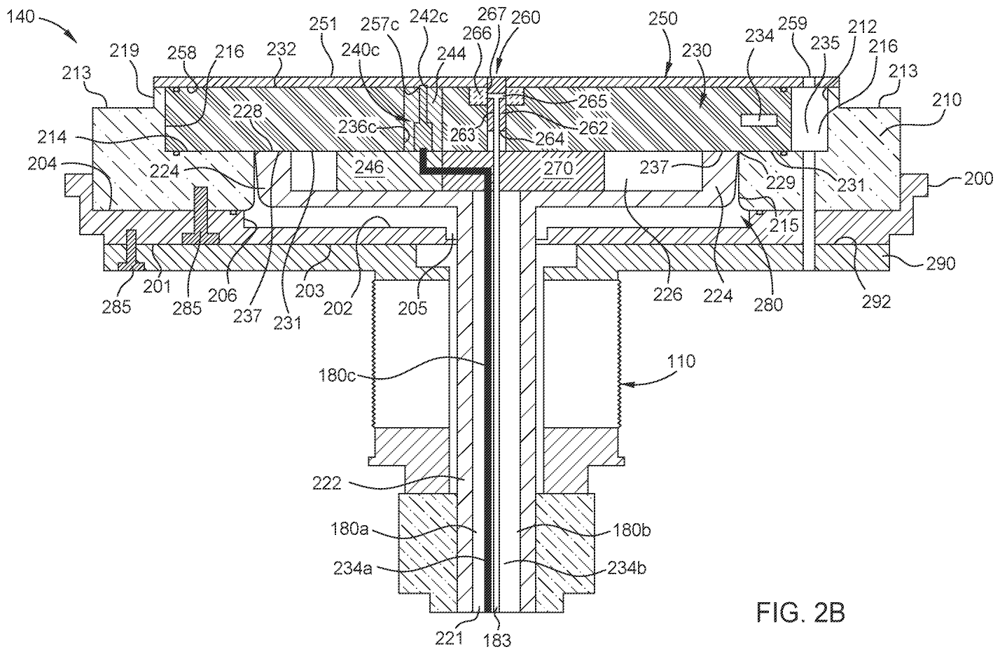

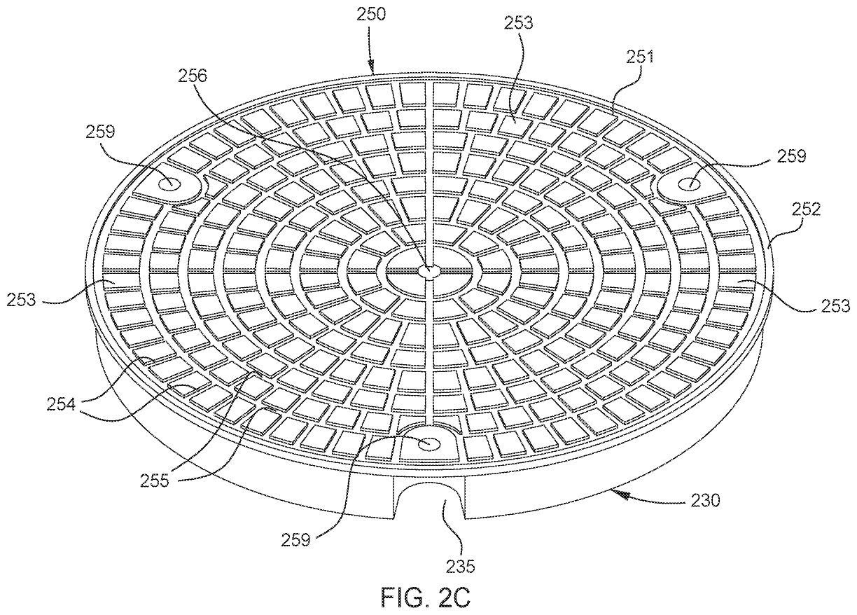

An electrostatic chuck assembly 140 is at least partially disposed within the interior volume 101 for supporting and chucking a substrate 130. The substrate 130 is placed on an upper surface (puck 250 as shown in FIG. 2A) of the electrostatic chuck assembly 140 during processing. A chucking power source 170 is coupled to chucking electrodes (e.g., first and second chucking electrodes 240a,b of FIG. 2A) in the electrostatic chuck assembly 140 by lines 180a,b to provide the power necessary to chuck the substrate 130 to the electrostatic chuck assembly 140. A first RF power supply 171 is connected to the electrostatic chuck assembly 140 to provide power to ignite the gases within the processing volume 103 to form the plasma 106. A second RF power supply 172 is connected to the electrostatic chuck assembly 140 to further excite the plasma 106 and to control the plasma 106 during processing of the substrate 130. A heat transfer gas supply 173 is connected to the electrostatic chuck assembly 140 by gas line 183 to provide a heat transfer gas that flows between the underside of substrate 130 and the upper surface of the electrostatic chuck assembly 140 to regulate the temperature of the substrate 130. A heat exchanger 174 is connected to the electrostatic chuck assembly 140 to circulate a coolant fluid into the electrostatic chuck assembly 140 to regulate the temperature of the substrate 130. The coolant fluid flows into the electrostatic chuck assembly 140 through a coolant supply line 184a that returns to the heat exchanger 174 through a coolant return line 184b.

The electrostatic chuck assembly 140 is coupled to a first lift mechanism 113 which provides vertical movement of the electrostatic chuck assembly 140 between an upper, processing position (as shown in FIG. 1) and a lower, transfer position (not shown). A bellows assembly 110 is coupled to the electrostatic chuck assembly 140 to provide a flexible seal that allows vertical motion of the electrostatic chuck assembly 140 while preventing fluid communication between the environment outside the process station 100 from and the interior volume 101. The bellows assembly 110 also includes a lower bellows flange 114 in sealed against a bottom surface 111 of chamber body 102 by one or more seals 115.

The process station 100 also includes a lift assembly 120, which includes lift pins 122 mounted on a platform 124 connected to a shaft 125. The shaft 125 is coupled to a second lift mechanism 126 for raising and lowering the lift assembly 120 relative to the electrostatic chuck assembly 140 so that the substrate 130 may be placed on or removed from the surface of the electrostatic chuck assembly 140. FIG. 1 shows the lift pins 122 in a lower position, but the lift pins 122 are moveable to an upper position (not shown) where the tips of the lift pins 122 protrude from the top of the electrostatic chuck assembly 140.

The electrostatic chuck assembly 140 includes thru-holes to receive the lift pins 122 such that the lift pins 122 can engage the underside of the substrate 130. A second bellows assembly 128 is coupled between the lift assembly 120 and the bottom surface 111 to provide a flexible seal which maintains processing pressure during the vertical motion of the lift assembly 120.

Operation of the process station 100 is controlled by a controller 190. The controller 190 includes a programmable central processing unit, here the CPU 191, which is operable with a memory 192 (e.g., non-volatile memory) and support circuits 193. The CPU 191 is one of any form of general-purpose computer processor used in an industrial setting, such as a programmable logic controller (PLC), for controlling various station components and sub-processors. The memory 192, coupled to the CPU 191, facilitates the operation of the process station 100. The support circuits 193 are conventionally coupled to the CPU 191 and comprise cache, clock circuits, input/output subsystems, power supplies, and the like, and combinations thereof coupled to the various components of the process station 100 to facilitate control of substrate processing operations therewith.

The instructions in memory 192 are in the form of a program product, such as a program that implements the methods of the present disclosure. In one example, the disclosure may be implemented as a program product stored on computer-readable storage media for use with a computer system. The program(s) of the program product define functions of the embodiments (including the methods described herein). Thus, the computer-readable storage media, when carrying computer-readable instructions that direct the functions of the methods described herein, are embodiments of the present disclosure.

FIGS. 2A-2B illustrate cross-sectional views of the electrostatic chuck assembly 140. The electrostatic chuck assembly 140 includes a housing 200, a body 210, an RF transmission tube 220, a heat transfer plate 230, a first chucking electrode 240a, a second chucking electrode 240b, a center tap electrode 240c, a puck 250, a plug assembly 260, and a manifold 270. The substrate 130 is chucked to the puck 250 during processing.

The housing 200 is coupled to the bellows 110 and supports the body 210. A lower surface 201 of the housing 200 is engaged with the upper surface 292 of a flange 290 of the bellows 110. The flange 290 may be secured to the housing 200 by one or more fasteners 285. The housing 200 includes an upper surface 202 that defines a housing recess 206. The upper surface 202 includes a bottom surface 203 and a shoulder surface 204. A port 205 is formed in the housing 200 and extends from the bottom surface 203 to the lower surface 201. A shaft 222 of the RF transmission tube 220 is disposed in the port 205. Lift pin thru-holes corresponding to lift pins 122 are formed in the housing 200. In some embodiments, the housing is made of a metal, such as aluminum. The housing 200 is connected to the ground 107.

The body 210 includes a lower surface 211 and an inner upper surface 212 separated from an outer upper surface 213 by a lip 219. The inner upper surface 212 defines a body recess 216 and includes a shoulder surface 214 and a central opening 215 that is formed through the body 210. The central opening 215 extends through the body 210 from the lower surface 211 to the shoulder surface 214 and may be cylindrical in shape. The housing recess 206 and the body recess 216 collectively define a cavity 280. The body 210 is at least partially disposed in the housing recess 206 with the lower surface 211 engaged with the shoulder surface 204 of the housing 200. The body 210 may be secured to the housing 200 by one or more fasteners 285. The outer upper surface 213 is a shoulder surface that may engage with the one or more shields 105 of the process station 100 (FIG. 1). The body 210 may be formed from an insulated material, such as a ceramic. For example, the body 210 may be formed from aluminum oxide.

The RF transmission tube 220 is configured to transfer RF power supplied from the first RF power supply 171 and second RF power supply 172 (FIG. 1) to the heat transfer plate 230. The RF transmission tube 220 includes the shaft 222 and a head 224. The head 224 may be a circular flange extending radially from the shaft 222 that is generally circular in shape. A bore 221 extends through the shaft 222 and is in communication with a head recess 226 formed in the head 224. The head recess 226 may be generally cylindrical in shape. The head 224 includes a head shoulder 228 configured to engage with the heat transfer plate 230. The head shoulder 228 may be a flat or substantially flat surface. An outside edge 229 of the head shoulder 228 is in contact with the heat transfer plate 230. In some embodiments, the outside edge 229 is in contact with the body 210, such as contacting the inner upper surface 212 within the opening 215. The head shoulder 228 may be a ring that extends around the edge of the head 224 where the edge 229 is the circumference of the ring. The electric lines 180a-180c, the coolant supply line 184a, the coolant return line 184b, and the gas line 183 extend through the bore 221 and into the head recess 226. The RF transmission tube 220 may be formed from copper or other material suitable to conduct RF power.

The head 224 is disposed in the cavity 280 underneath the heat transfer plate 230. In some embodiments, the head 224 is disposed in the opening 215. The thickness of the head 224, shown as DH, may be the same or substantially the same as the thickness of the opening 215 formed in the body 210, shown as DB. The shoulder surface 214 and the head shoulder 228 may be co-planar as shown in FIG. 2A.

The heat transfer plate 230 is disposed in the body recess 216 and includes a lower surface 231 and an upper surface 232. The heat transfer plate 230 may be secured to the body 210 by one or more fasteners (not shown). A coolant channel 234 is disposed in the heat transfer plate 230. Coolant fluid circulates through the coolant channel 234 from the heat exchanger 174 (FIG. 1) to regulate the temperate of the substrate 130 that is disposed on the puck 250. The coolant channel 234 has an inlet 234a connected to the coolant supply line 184a and an outlet 234b connected to the coolant return line 184b. The coolant fluid may be deionized water or any other suitable coolant fluid, gas or liquid. The heat transfer plate 230 also includes a first opening 236a, a second opening 236b, and a third opening 236c to receive the electrodes 240a, 240b, 240c. The openings 236a-c may be spaced to minimize creepage of the chucking voltage supplied to the first and second chucking electrodes 240a, 240b through the heat transfer plate 230. A plug port 238 extends through the heat transfer plate 230 that houses the plug assembly 260. The plug port 238 also includes a stop shoulder 239. The plug port 238 may extend along the centerline of the heat transfer plate 230.

The lower surface 231 is engaged with the shoulder surface 214 of the body 210 and with the head shoulder 228 of the head 224. The head shoulder 228 contacts a continuous area 237 of the lower surface 231 that extends around the periphery of the openings 236a-c. The outer boundary of the continuous area 237 is where the outer edge 229 of the head 224 engages the lower surface 231. In some embodiments, the continuous area 237 is an annular area of the lower surface 231 that contacts the ring shaped head shoulder 228. RF power supplied to the RF transmission tube 220 is transferred to the heat transfer plate 230 at the continuous interface between the head shoulder 228 and the continuous area 237. This interface may be secured by fasteners (not shown) that secure the head 224 to the heat transfer plate 230. Due to the skin effect, the RF power primarily flows through skin (i.e., outer surface) of the RF transmission tube 220. Similarly, RF power is transferred from the RF transmission tube 220 to the heat transfer plate 230 at the edge of the continuous interface. In other words, the RF power primarily flows into the heat transfer plate 230 where the outer edge 229 of the head 224 contacts the lower surface 231 of the heat transfer plate 230. This RF power is then transferred trough the heat transfer plate 230 to the puck 250, where the RF power is able to generate an electromagnetic field that interact with gases of the processing volume 103 to ignite a plasma or to maintain or adjust a plasma.

In conventional electrostatic chucks, the RF power is supplied to chucking electrodes embedded in the puck. This RF power is used to ignite and maintain plasma. However, conventional RF transmission through the electrodes embedded in the puck has a tendency to shift the plasma to one side or portion of the substrate. The plasma also shifts as the current alternates. Without being bound by theory, it is believed that the multiple discontinuous electrodes transferring RF power to the puck results in differentials in the magnetic field flowing through the plasma that causes the plasma to shift. As a result, the etch rate may be different at different locations on the substrate.

The electrostatic chuck assembly 140 generates plasma that is more evenly distributed over the surface of the substrate 130 to reduce a differential in the etch rate at different locations on the surface of the substrate 130. RF power supplied by the first and second RF power supplies 171, 172 flows through the single RF transmission tube 220 rather than through multiple RF conductors. Without being bound by theory, it is believed that the continuous interface of the head 224 with the heat transfer plate 230 distributes the RF power in a more even fashion that reduces or substantially eliminates plasma shift such that the plasma is more evenly distributed over the surface of the substrate 130. Additionally, it is believed that placing the interface nearer the edge of the heat transfer plate 230 decreases the effect of the plasma shift. Furthermore, the electrostatic chuck assembly 140 has an increased etch rate. For example, the etch rate may be about 5.9 Å/s. The reduction and/or elimination of the shift of the plasma and the increased etch rate increases the throughput of substrate processes performed in the station 100.

The first and second RF power supplies 171, 172 may be connected to the shaft 222 of the RF transmission tube 220 by a strap, represented as line 181. In some embodiments, the first power supply 171 is configured to supply RF power at 13.56 MHz and the second RF power supply 172 is configured to supply RF power at about 60 MHz. In some embodiments, the first RF power supply 171 supplies RF power between 300 W and 800 W, such as between 330 W and 360 W. In some embodiments, the second RF power supply 172 supplies RF power between 800 W and 1000 W, such as between 880 W and 960 W. The power of the RF power supplied by the first and second RF power supplies 171, 172 may be the same or substantially the same even though the frequency of the RF power differs. For example, the first RF power supply may provide RF power at 800 V at about 13.56 MHz while the second RF power supply provides RF power at 800V at about 60 MHz. The first and second power supplies may be connected to an RF filter, such as a 59 uH RF filter. For example, the first and second power supplies may be configured to supply power at 300 W and 800 W, respectively, with the etch rate being about 5.9 Å/s.

In some embodiments, RF power may be supplied to the RF transmission tube 220 from both the first and second RF power supplies 171, 172 simultaneously. For example, the first RF power supply 171 may initially supply RF power to the RF transmission tube 220 to ignite the plasma 106. After the plasma is ignited, then RF power is supplied to the RF transmission tube 220 from the second RF power supply 172 to further excite and/or control the plasma 106. The first RF power supply 171 may continue to provide RF power while RF power is being supplied from the second RF power supply 172. However, the first RF power supply 171 may stop supplying RF power after the plasma 106 is ignited and the second RF power supply 172 has started supplying RF power to the RF transmission tube 220.

The first chucking electrode 240a and second chucking electrode 240b transfer a chucking voltage to the puck 250 to generate an electrostatic force that clamps the substrate 130 to the puck 250. The electrostatic chuck assembly 140 is bipolar because the first chucking electrode 240a and the second chucking electrode 240b are electrically biased relative to one another. A bipolar chuck does not require the presence of a plasma to generate an electrostatic clamping force unlike a monopolar chuck that only has one chucking electrode. The center tap electrode 240c is disposed between the first chucking electrode 240a and second chucking electrode 240b.

Each electrode 240a-c includes a body portion 244 and a respective contact 242a, 242b, 242c configured to engage an associated contact 257a-c of the puck 250. The electrodes 240a-c are disposed in the body recess 216 between the shoulder surface 214 and the upper surface of the lip 219. In some embodiments, the contact 242a-c of each electrode 240a-c may extend beyond the upper surface 232 of the heat transfer plate 230 and the upper surface of the lip 219 while the body portion 244 of each electrode 240a-c is disposed between the upper surface of the lip 219 and the shoulder surface 214. The electrodes 240a-c are positioned in the respective openings 236a-c of the heat transfer plate 230. The electrodes 240a-c may be seated on and supported by a support member 246 disposed in the head recess 226 beneath the heat transfer plate 230. The electrodes 240a-c are connected to the chucking power source 170 by a respective electric line 180a-c that extend through the bore 221 and into the head recess 226. In some embodiments, the support member 246 is a Teflon cable holder that supports the electric lines 180a-c within the head recess 226.

The voltage at the center tap electrode 240c is monitored, such as being monitored by the controller 190, to determine the voltage drop across the substrate 130. If an unequal voltage drop is detected, then the voltage of the first and second chucking electrodes 240a, 240b, or the voltage of the center tap electrode 240c, may be adjusted to equalize the voltage drop. Thus, the center tap electrode 240c is used to maintain a constant voltage differential on opposite sides of the substrate 130 to keep the substrate chucked to the puck 250. In some embodiments, the chucking electrodes 240a, 240b each supply a chucking voltage of 800V at opposing polarities to the puck 250 to generate the electrostatic force. The electric line 180c connected to the center tap electrode 240c may be used to monitor the voltage at center tap electrode 240c. This electric line 180c may be connected to the chucking power source 170 or to the controller 190.

FIGS. 2A-2C illustrate the puck 250. The puck 250 is disposed on the heat transfer plate 230. The puck 250 is made of a dielectric material, such as aluminum nitride. In some embodiments, the puck 250 is formed by sintering. The substrate 130 is chucked to and supported by the puck 250 during processing. The puck 250 is thinner than conventional pucks because electrodes are not disposed in the puck 250, which omits the need for the puck to exceed the thickness of the electrode and avoids issues relating to differentials in heat transfer coefficients caused by embedded electrodes. Instead, the electrodes 240a, 240b, 240c are embedded in the heat transfer plate 230. For example, the puck 250 may have a thickness of about 4 mm whereas a conventional puck has a thickness of about 10 mm. In some embodiments, the puck 240 has a thickness less than 4 mm. Conventional pucks containing electrodes are coated in a dielectric material to cover the electrodes embedded therein. In some embodiments, the puck 250 is not coated with a dielectric material like a conventional puck since electrodes are not disposed in the puck 250. Thus, the puck 250 may be an uncoated puck. The electrodes 240a, 240b, 240c are in contact with a corresponding contact point 257a-c formed on a lower surface 258 of the puck 250.

FIG. 2C illustrates a top axonometric view of the puck 250 disposed on the heat transfer plate 230. An upper surface 251 of the puck 250 may be bounded by a peripheral ring 252 and may include a plurality of raised wedge-shaped mesas 253. The mesas 253 are defined by intersecting radial channels 254 and circular channels 255 configured to distribute a heat transfer gas supplied from the heat transfer gas supply 173 (FIG. 1) and delivered through an opening 256 formed in the puck 250. Each lift pin thru-holes 259 formed through the puck 250 is aligned with a corresponding lift pin thru-holes 235 of the heat transfer plate 230 and a corresponding thru-hole formed in the body 210, housing 200, and flange 290 to receive a lift pin 122 (FIG. 1). These aligned thru-holes are shown in FIG. 2B.

The heat transfer gas flows between the underside of the substrate 130 and the upper surface 251 of the puck 250 through the channels 254, 255 in order to regulate the temperature of the substrate 130. The heat transfer gas supplied by the heat transfer gas supply 173 may be an inert gas, such as argon gas. The peripheral ring 252 contacts the underside of the substrate 130 near its edge which helps control the amount of heat transfer gas which escapes from behind the substrate 130. As shown in FIG. 2A, the puck 250 may be sized such that the bottom surface of the peripheral ring 252 extends beyond the edge of the heat transfer plate 230 and is engaged with the lip 219. In some embodiments, the bottom surface of the peripheral ring 252 may instead be engaged with the upper surface 232 of the heat transfer plate 230.

The one or more mesas 253 which are disposed between intersecting channels 254, 255 may comprise square or rectangular blocks, cones, wedges, pyramids, posts, cylindrical mounds, or other protrusions of varying sizes, or combinations thereof that extend up from the puck 250 and support the substrate 130. In one embodiment, the height of the mesas 253 may range from about 50 microns (micrometers) to about 700 microns, and the width (or diameter) of the mesas 253 may range from about 500 microns to about 5000 microns. In another example, the puck 250 may include an upper surface 251 having a plurality of channels (e.g., radial channels 254) formed therein and which does not include mesas 253. In some embodiments, the puck 250 includes channels arranged in a grid like pattern or a circular pattern. Alternately, radial patterns may be combined with grid and circular patterns. Other geometries may also be used for the pattern of channels of the puck 250.

In some embodiments, the contact points 257a-c may be a blind bore formed in the lower surface 258 of the puck 250 to receive a respective contact 242a-c as shown in FIG. 2A. In some embodiments, the contact points 257a-c are a portion of the lower surface 258 where the respective contact 242a-c contacts the lower surface 258. In some embodiments, the contact points 257a-c may be an indentation formed on the lower surface 258 in which the respective contact 242a-c is partially inserted. In some embodiments, the contact points 257a-c may each be a protrusion extending from the lower surface 258 configured to engage with a respective contact 242a-c.

A robust electrostatic force chucking the substrate 130 to the puck 250 is necessary to supply the heat transfer gas without causing the substrate 130 to move about the surface of the puck 250 due to the pressure of the gas. Movement of the substrate 130 across the surface of the puck 250 can damage the puck 250 and the substrate 130. Thus, the chucking force provided by the electrodes 240a, 240b allow for pressurized heat transfer gas to flow through the channels 254, 255 without moving the substrate 130. The pressure and flow rate of the heat transfer gas may be adjusted to help regulate the temperature of the substrate 130.

Referring to FIG. 2A, the plug assembly 260 is disposed in the plug port 238 of the heat transfer plate 230 to facilitate flowing the heat transfer gas into the channels 254, 255. The plug assembly 260 includes a plug 262 and a sleeve 266. The plug 262 may extend at least partially into the opening 256 of the puck 250. The plug 262 includes a flow path 263. The inlet 264 of the flow path 263 is is connected to the heat transfer gas supply 173 (FIG. 1) via the gas line 183. The plug 262 also includes one or more radial outlets 265 formed on the side of the plug 262.

The plug 262 is disposed in a central opening 267 of the sleeve 266. The sleeve 266 is engaged with the stop shoulder 239 of the heat transfer plate 230. The sleeve 266 may be formed of an insulating material. A flow annulus is present between the surface of the central opening 267 and the plug 262 such that heat transfer gas flowing through the flow path 263 exits at the one or more radial outlets 265 and then flows upwards through the flow annulus and out the opening 256 formed into the puck 250 and into the channels 254, 255.

A portion of the coolant supply line 184a, the coolant return line 184b, and a portion of the gas line 183 may be formed in the manifold 270. The manifold 270 is disposed in the head recess 226 beneath the heat transfer plate 230. The manifold 270 may be at least partially disposed in an opening or recess formed in the support member 246. In some embodiments, the manifold 270 is disposed underneath the heat transfer plate 230 between the first and second chucking electrodes 240a, 240b.

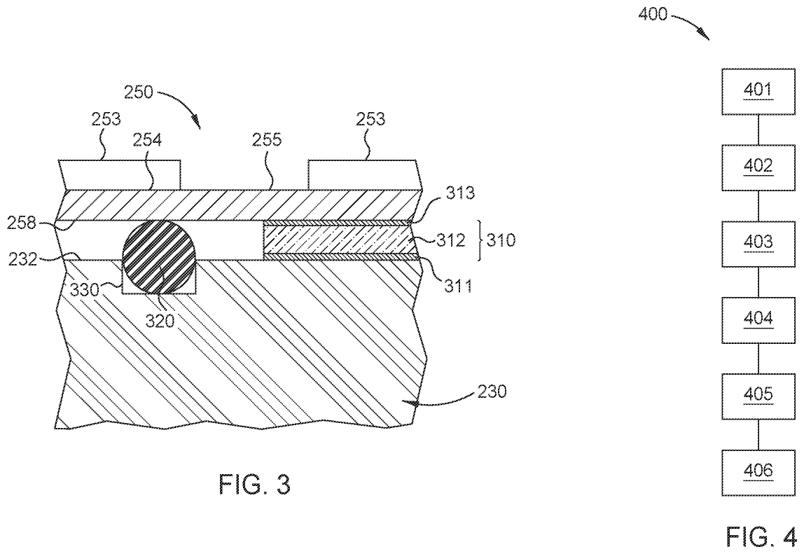

FIG. 3 illustrates a partial cross-section of FIG. 2A to illustrate a bond 310 that secures the puck 250 to the heat transfer plate 230. As shown, the lower surface 258 of the puck 250 is secured to the opposing upper surface 232 of the heat transfer plate 230 by the bond 310. Without being bound by theory, it is believed that bonding the puck 250 to the heat transfer plate 230 facilitates efficient transfer of RF power and heat between the engaged opposing surfaces of the puck 250 and the heat transfer plate 230. Additionally, the bond 310 may be selected to maintain the engagement of the puck 250 and the heat transfer plate 230 despite the thermal expansion in the puck 250 and heat transfer plate 230. In some embodiments, the bond 310 may be a multilayer bond that includes a first indium layer 311, a second indium bond layer 312, and a nono bond layer 313 disposed between the first and second indium bond layers 311, 312. The bond 310 may alternatively be made by any other suitable adhesive. In some embodiments, the bond 310 may only be disposed about the periphery of the lower surface 258 of the puck 250 as shown in FIG. 3. The bond 310 may act as a seal to prevent process gases within the processing volume 103 from leaking into the cavity 280 around the edge of the puck 250. FIG. 3C is exaggerated to show the bond 310. The lower surface 258 of the puck 250 may be in contact with the upper surface 232 of the heat transfer plate 230 with the bond 310 disposed therebetween rather than a gap being present between the two opposing surfaces 258, 231 as shown in FIG. 3.

As shown in FIG. 3, a seal 320 may be disposed in a groove 330 formed in the upper surface 232 of the heat transfer plate 230 and engaged with the underside of the puck 250. The seal 320 may be disposed adjacent to the bond 310 as shown in FIG. 3. The seal 320 is configured to isolate the cavity 280 from the processing volume 103 (FIGS. 1 and 2A-2C), such maintaining the isolation of the cavity 280 should process gases leak through the bond 310. Additional seals (not shown) may be disposed in the electrostatic chuck assembly 140 to isolate the cavity 280 from the processing volume 103. For example, one or more seals may be disposed between the heat transfer plate 230 and the body 210 and one or more seals may be disposed between the housing 200 and the body 210. One or more seals may be disposed in the openings 236a-c to seal against a respective electrode 240a-c. One or more seals may also be disposed between the heat transfer plate 230 and the underside of the puck 250 adjacent the plug assembly 260 and opening 256 to prevent heat transfer gases from leaking behind the underside of the puck 250.

FIG. 4 illustrates a method 400 of processing a substrate 130 within the process station 100. The method 400 may be executed by the controller 190. As shown by activity 401, the substrate 130 is first positioned onto the puck 250. The substrate 130 may enter the processing volume 103 through an opening (not shown) in the chamber body 102 engaged with a transfer robot (not shown) or on a carrier (not shown) levitated by one or more magnetic rails (not shown) disposed in the processing volume 103.

The second lift mechanism 126 is used to move the lift pins 122 into an upper position such that the tips of the lift pins 122 extend above the upper surface 251 of the puck 250 to lift the substrate 130 off of the robot or carrier. Each lift pin 122 is able to move within respective aligned lift-pin thru-holes formed in the housing 200, body 210, heat transfer plate 230 (see thru-holes 235), puck 250 (see thru-holes 259), and the flange 290. The second lift mechanism 126 then moves the lift pins 122 to the lower position to engage the underside of the substrate 130 with the upper surface 251 of the puck 250, thereby transferring the substrate 130 to the puck 250.

As shown by activity 402, the substrate 130 is chucked to the puck 250. To chuck the substrate 130, opposing chucking voltages are supplied to the first chucking electrode 240a and the second chucking electrode 240b from the chucking power source 170. For example, a current with a positive 800V may be supplied to the first chucking electrode 240a while a current with a negative 800V may be supplied to the second chucking electrode 240b. The voltage at the center tap electrode 240c is monitored. If an unequal voltage drop is detected, then the voltage of the first and second chucking electrodes 240a,b, or the voltage of the center tap electrode 240c, may be adjusted to equalize the voltage drop.

As shown by activity 403, the plasma 106 is ignited within the processing volume 103. One or more process gases are supplied into processing volume 103 from the gas supply 109. The first RF power supply 171 provides RF power to the RF transmission tube 220 which is used to ignite the process gases to form the plasma 106. For example, the first RF power supply 171 may supply RF power at 800 W and 13.56 MHz to the RF transmission tube 220 to ignite the process gases to form the plasma 106. In some embodiments, the substrate 130 is subjected to one or more processes within the processing volume 103 prior to igniting the plasma 106.

As shown by activity 404, the substrate 130 is processed using the plasma 106. For example, the plasma 106 may be used to etch the surface of the substrate 130. To process the substrate 130 with the plasma 106, the second RF power supply 172 may supply RF power to the RF transmission tube 220 to further excite and/or control the plasma 106. For example, the second RF power supply 172 may supply RF power at 800 W at 60 MHz. In some embodiments, both the first and second RF power supplies 171, 172 supply RF power to the RF transmission tube 220 during plasma processing. In some embodiments, the first RF power supply 171 may stop supplying RF power to the RF transmission tube 220 after the second RF power supply 172 has supplied RF power for a period of time.

The temperate of the substrate 130 is regulated during both activities 403 and 404 and during other processes performed in the processing volume 103. For example, the substrate 130 may need to be cooled. The heat transfer gas supply 173 flows gas through the electrostatic chuck assembly 140 and into the channels 254, 255 to help regulate the temperature of the substrate 130. The heat transfer gas may be maintained at a steady flow rate and/or pressure during plasma ignition and/or plasma processing. The flow rate and/or pressure of the heat transfer gas may be adjusted to regulate the temperature of the substrate 130. A coolant fluid is circulated from the heat exchanger 174 through the coolant channel 234 to help regulate the temperature of the substrate 130. For example, the flow rate of the coolant may be adjusted to change the temperature of the substrate 130. The coolant channel 234 provides for uniform cooling of the substrate 130 which minimizes outgassing that could otherwise interfere with the chucking of the substrate 130 to the puck 250.

As shown by activity 405, the substrate 130 is de-chucked from the puck 250. To de-chuck the substrate 130, a current is supplied from the chucking power source 170 to each chucking electrode 240a,b that is opposite in polarity of the current used to chuck the substrate 130 for a period of time. Supplying a current at the opposite polarity reduces and/or eliminates residual charges in the puck 250 and/or the substrate 130. For example, a current may have been supplied at positive 800V to the first chucking electrode 240a to chuck the substrate. A de-chuck current at about negative 175V may be supplied to the first chucking electrode 240a for a period of time, such as between 1 and 5 seconds, to de-chuck the substrate 130. A similar de-chuck current of positive 175V may be supplied to the second chucking electrode 240b when a chucking voltage of negative 800V was supplied to the second electrode 240b to chuck the substrate 130.

After the substrate 130 is de-chucked, the substrate 130 is removed from the puck 250 as shown by activity 406. The substrate 130 is removed from the puck 250 by lifting the substrate 130 off the puck 250 by using the lift pins 122. The second lift mechanism 126 moves the lift pins 122 to the upper position to lift the substrate off the puck 250 and to position the substrate 130 for transfer back to the transfer robot or carrier.

The process 400 may be repeated to fabricate an additional substrate. In some embodiments, the polarities of the first chucking electrode 240a and the second chucking electrode 240b are reversed during a subsequent process 400. Flipping the polarities further reduces and/or eliminates residual charges within the electrostatic chuck assembly 140.

In some embodiments, activities 403, 404 may be omitted. The substrate 130 is instead subjected to one or more processes within the processing volume 103 while chucked to the puck 250 without supplying RF power to the RF transmission tube 220.

While the foregoing is directed to embodiments of the present disclosure, other and further embodiments of the disclosure may be devised without departing from the basic scope thereof, and the scope thereof is determined by the claims that follow.

1. An electrostatic chuck assembly, comprising:
a body including a body recess;
a heat transfer plate disposed in the body recess, wherein the heat transfer plate includes an upper surface, a lower surface, a coolant channel, a first opening, and a second opening;
an RF transmission tube configured to transfer RF power to the heat transfer plate, the RF transmission tube including a shaft connected to a head with a head recess formed therein, wherein a head shoulder of the head contacts a continuous area of the lower surface of the heat transfer plate;
a puck engaged with the upper surface of the heat transfer plate;
a first chucking electrode disposed in the first opening and a second chucking electrode is disposed in the second opening, wherein the first and second chucking electrodes are configured to transfer a chucking voltage to the puck.

2. The electrostatic chuck assembly of claim 1, further comprising:
a bond securing the puck to the heat transfer plate, wherein the bond is disposed about a periphery of a lower surface of the puck.

3. The electrostatic chuck assembly of claim 2, wherein the bond is a multi-layer bond.

4. The electrostatic chuck assembly of claim 1, further comprising:
a housing including a housing recess secured to the body, wherein the shaft of the RF transmission tube is disposed in a port formed in the housing.

5. The electrostatic chuck assembly of claim 1, wherein the puck is a sintered puck.

6. The electrostatic chuck assembly of claim 1, wherein the puck has a thickness of 4 mm or less.

7. The electrostatic chuck assembly of claim 1, wherein a contact of the first and second chucking electrodes extends into a respective contact point formed in the puck.

8. The electrostatic chuck assembly of claim 1, wherein the head is circular in shape and the head shoulder is a ring.

9. The electrostatic chuck assembly of claim 1, wherein the head is disposed in an opening of the body recess, wherein the opening extends from a lower surface of the body to a shoulder surface of the body engaged with the lower surface of the heat transfer plate.

10. The electrostatic chuck assembly of claim 1, further comprising:
a plug assembly disposed in a plug port formed in the heat transfer plate, wherein the plug assembly is configured to distribute a heat transfer gas to an opening formed in the puck connected to a plurality of channels formed in an upper surface of the puck.

11. The electrostatic chuck assembly of claim 10, further comprising:
a first electric line in connection with the first chucking electrode;
a second electric line in connection with the second chucking electrode;
a coolant supply line connected with an inlet of the coolant channel;
a return coolant line connected to an outlet of the coolant channel; and
a gas supply line configured to supply the heat transfer gas to the plug assembly, wherein the first and second electric lines, the coolant supply line, the coolant return line, and the gas supply line are partially disposed in a bore of the shaft of the RF transmission tube.

12. The electrostatic chuck assembly of claim 11, further comprising:
a manifold disposed in the head recess, wherein the coolant supply line, coolant return line, and the gas supply line are partially disposed in the manifold.

13. An electrostatic chuck assembly, comprising:
a body including a body recess;
a heat transfer plate disposed in the body recess, wherein the heat transfer plate includes an upper surface, a lower surface, a first opening, and a second opening;
an RF transmission tube configured to transfer RF power to the lower surface of the heat transfer plate, the RF transmission tube including:
a shaft including a bore; and
a head extending from the shaft and including a recess in communication with the bore, wherein the head is engaged with the lower surface of the heat transfer plate;
a puck bonded to the upper surface of the heat transfer plate;
a first chucking electrode disposed in the first opening and a second chucking electrode is disposed in the second opening, wherein the first and second chucking electrodes are configured to transfer a chucking voltage to the puck.

14. The electrostatic chuck assembly of claim 13, wherein a bond between the upper surface of the heat transfer plate and the puck is disposed about a periphery of a lower surface of the puck.

15. The electrostatic chuck assembly of claim 14, wherein the bond is a multi-layer bond.

16. A method of processing a substrate, comprising:
chucking a first substrate to a puck bonded to an upper surface of a heat transfer plate by applying a chucking voltage to the puck using a first chucking electrode and a second chucking electrode disposed in the heat transfer plate, wherein first and second chucking electrode have opposing polarities;
igniting a plasma above the first substrate chucked to the puck using a first RF power, wherein the first RF power is transferred from an RF transmission tube to the heat transfer plate at a continuous interface between the heat transfer plate and a head of the RF transmission tube, wherein the head extends from a shaft of the RF transmission tube and includes a head recess that is in communication with a bore of the shaft; and
processing the first substrate using a second RF power, wherein the second RF power is transferred from the RF transmission tube to the heat transfer plate at the continuous interface.

17. The method of claim 16, further comprising:
processing the first substrate with one or more process gases prior to igniting the plasma.

18. The method of claim 16, wherein the first RF power is at 800 W with a frequency of 13.56 MHz and the second RF power is at 800 W with a frequency of 60 MHz.

19. The method of claim 16, further comprising:
regulating a temperature of the first substrate by supplying a coolant fluid through a coolant supply line to a coolant channel of the heat transfer plate and by supplying heat transfer gas through a gas line to an opening in the puck, wherein the gas line and the coolant supply line are disposed in the RF transmission tube.

20. The method of claim 16, further comprising:
de-chucking the first substrate from the puck by reversing the polarities of the first and second chucking electrodes.
